(19) United States
(12) Patent Application Publication
(10) Pub. No.: US 2024/0072081 A1
(43) Pub. Date: Feb. 29, 2024

(54) IMAGE SENSOR

(71) Applicant: SAMSUNG ELECTRONICS CO., LTD., Suwon-Si (KR)

(72) Inventors: JAEKWAN SEO, SUWON-SI (KR); NOSAN PARK, SUWON-SI (KR); WONCHUN YANG, SUWON-SI (KR); KIBUM YU, SUWON-SI (KR); HARAM YU, SUWON-SI (KR)

(21) Appl. No.: 18/113,923

(22) Filed: Feb. 24, 2023

(30) Foreign Application Priority Data
Aug. 24, 2022 (KR) 10-2022-0106348

(51) Int. Cl. H01L 27/146

(52) U.S. Cl. CPC H01L 27/14612; H01L 27/14621; H01L 27/14623; H01L 27/14627; H01L 27/14685; H01L 27/14689

(57) ABSTRACT

An image sensor includes a pixel, a rear side anti-reflective layer on the pixel, a color filter on the rear side anti-reflective layer, a color filter cover layer on the color filter, a passivation layer on the color filter cover layer, a microlens on the passivation layer, a first capping layer on the microlens, and a second capping layer on the first capping layer.

### CROSS-REFERENCE TO RELATED APPLICATION

This application claims priority under 35 U.S.C. § 119 to Korean Patent Application No. 10-2022-0106348 filed on Aug. 24, 2022 in the Korean Intellectual Property Office, the subject matter of which is hereby incorporated by reference in its entirety.

### BACKGROUND

The inventive concept relates generally to image sensors, and more particularly, to complementary metal-oxide semiconductor (CMOS) image sensors.

Image sensors (e.g., CMOS image sensors) capable of capturing images and converting captured images into corresponding electrical signals may be included in a variety of consumer electronic devices, such as digital cameras, mobile phone cameras, portable camcorders, etc. Such image sensors may also be included various cameras incorporated into vehicles, security devices, robots, etc.

Image sensors may include a plurality of pixels variously arranged in a two dimensional matrix of rows and columns. In this regard, continuing design and development efforts seek to decrease the size of image sensors, thereby increasing integration density, while maintaining or improving image sensor performance.

### SUMMARY

Embodiments of the inventive concept provide image sensors exhibiting reduced size, improved performance and greater reliability.

According to an aspect of the inventive concept, an image sensor may include; a pixel, a rear side anti-reflective layer on the pixel, a color filter on the rear side anti-reflective layer, a color filter cover layer on the color filter, a passivation layer on the color filter cover layer, a microlens on the passivation layer, a first capping layer on the microlens, and a second capping layer on the first capping layer.

According to an aspect of the inventive concept, an image sensor may include; a first pixel, a second pixel spaced apart from the first pixel, a pixel isolation structure between the first pixel and the second pixel, a rear side anti-reflective layer on the first pixel, the second pixel, and the pixel isolation structure, a color filter on the rear side anti-reflective layer and including a first color filter on the first pixel and a second color filter on the second pixel, a color filter cover layer on the color filter, a passivation layer on the color filter cover layer, a microlens on the passivation layer, a first capping layer on the microlens, and a second capping layer on the first capping layer, wherein the color filter cover layer is conformally coated on the color filter.

According to an aspect of the inventive concept, an image sensor may include; a first pixel, a second pixel spaced apart from the first pixel, a pixel isolation structure between the first pixel and the second pixel, a first rear side anti-reflective layer on the first pixel, the second pixel, and the pixel isolation structure, a fence on the first rear side anti-reflective layer and aligned with the pixel isolation structure, a second rear side anti-reflective layer on the first rear side anti-reflective layer and the fence, a color filter on the second rear side anti-reflective layer and including a first color filter on the first pixel and a second color filter on the second pixel, a color filter cover layer on the color filter, a passivation layer on the color filter cover layer, a microlens on the passivation layer, a first capping layer on the microlens, and a second capping layer on the first capping layer, wherein the color filter cover layer is conformally coated on the color filter, and the second capping layer is conformally coated on the microlens.

### BRIEF DESCRIPTION OF THE DRAWINGS

Advantages, benefits and features, as well as the making and use of the inventive concept will be more clearly understood upon consideration of the following detailed description together with the accompanying drawings in which:

FIG. 1 is an exploded block diagram illustrating an image sensor 100 according to embodiments of the inventive concept;

FIG. 2 is a circuit diagram further illustrating pixels that may be included in the image sensor 100 of FIG. 1;

FIG. 3 is a plan (or top-down) view further illustrating the image sensor 100 of FIGS. 1 and 2;

FIG. 4 is a cross-sectional view further illustrating the image sensor 100 taken along line A-A′ of FIG. 3;

FIG. 5 is an enlarged view of region ‘C’ indicated in FIG. 4;

FIG. 6 is a cross-sectional view illustrating another image sensor 100a according to embodiments of the inventive concept;

FIGS. 7A, 7B, 7C, 7D, 7E, 7F and 7G (hereafter collectively, “FIGS. 7A to 7G”) are related cross-sectional views illustrating in one embodiment a method of manufacturing an image sensor according to embodiments of the inventive concept;

FIGS. 8A and 8B are related cross-sectional views illustrating in one embodiment a method of manufacturing an image sensor according to embodiments of the inventive concept;

FIG. 9 is a block diagram illustrating an image sensor according to embodiments of the inventive concept;

FIG. 10 is a block diagram illustrating a camera that may incorporate one or more image sensor(s) according to embodiments of the inventive concept; and

FIG. 11 is a general block diagram illustrating an imaging system that may include one or more image sensors according to embodiments of the inventive concept.

### DETAILED DESCRIPTION

Throughout the written description and drawings, like reference numbers and labels are used to denote like or similar elements, components, systems and/or method steps.

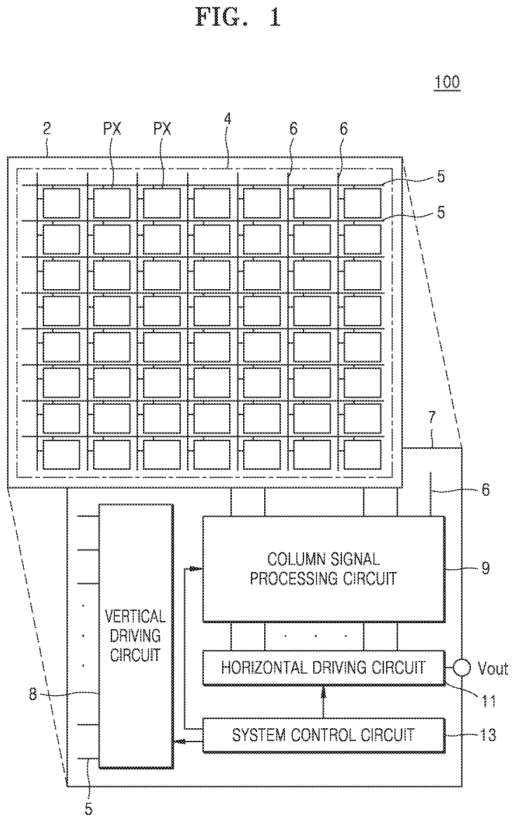

FIG. 1 is an exploded block diagram illustrating an image sensor 100 according to embodiments of the inventive concept.

Referring to FIG. 1, the image sensor 100 may be a stacked image sensor including a first substrate 2 and a second substrate 7. Here, the image sensor 100 may be a complementary metal-oxide semiconductor (CMOS) image sensor.

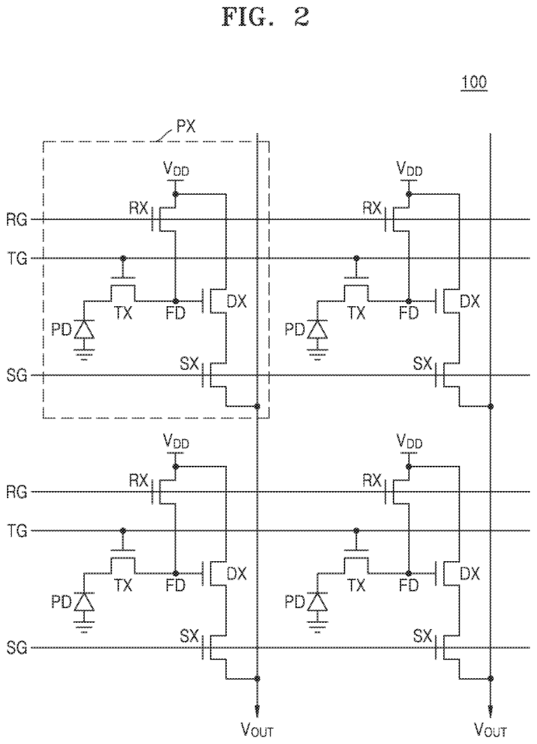

The image sensor 100 may be implemented by stacking, bonding and electrically connecting the first substrate 2 on the second substrate 7, wherein the first substrate 2 is a sensor substrate including a pixel circuit, and the second substrate 7 is a support substrate including a logic circuit driving the pixel circuit and otherwise supporting operation of the first substrate 2. In this regard, various features described in relation to FIGS. 2, 3, 4, 5, 6, 7A to 7G, 8A and 8B may find application primarily with respect to the first substrate 2.

As shown in FIG. 1, the first substrate 2 may includes a pixel array region 4 in which a number of unit pixels (hereafter “pixels”) PX including photoelectric conversion regions may be regularly arranged in a two dimensional matrix (e.g., an array or arrangement of rows and columns). Within the pixel array region 4, pixel driving lines 5 may extend in a designated row direction, and vertical signal lines 6 may extend in a designated column direction. Accordingly, a pixel PX may be arranged in such a manner that it is connected to one pixel driving line 5 and one vertical signal line 6.

Those skilled in the art will recognize that each pixel PX may include a photoelectric conversion unit and a pixel circuit including a charge storage unit. Here, the photoelectric conversion unit and the charge storing unit may variously include transistor(s) (e.g., metal oxide semiconductor (MOS) transistors) and/or capacitive element(s).

Those skilled in the art will further appreciate that the second substrate 7 may include various logic circuits and/or power circuits (e.g., a vertical driving circuit 8, a column signal processing circuit 9, a horizontal driving circuit 11, and a system control circuit 13) capable of driving each of the pixels PX included in the first substrate 2. In this regard, the image sensor 100 may be configured to provide an output voltage Vout through the horizontal driving circuit 11.

FIG. 2 is a circuit diagram further illustrating pixels PX that may be included in the image sensor 100 of FIG. 1.

Referring to FIGS. 1 and 2, the image sensor 100 is assumed in one example to include a plurality of pixels PX arranged in a matrix, wherein each of the plurality of pixels PX include a transmission transistor TX as well as various logic transistors, such as a reset transistor RX, a selection transistor SX, and a drive transistor DX (e.g., a source follower transistor). Here, the reset transistor RX may include a reset gate RG, the selection transistor SX may include a selection gate SG, and the transmission transistor TX may include a transmission gate TG.

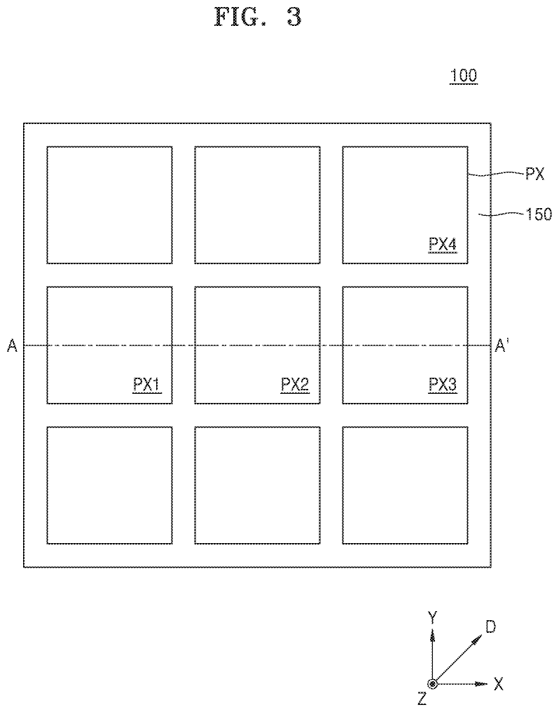

Each of the plurality of pixels PX includes a photoelectric conversion device PD and a floating diffusion region FD, wherein the photoelectric conversion device PD may correspond to a photoelectric conversion region described hereafter in relation to FIGS. 3, 4, 5, 6, 7A to 7G, 8A and 8B. However, regardless of specific configuration, the photoelectric conversion device PD may be used to generate and accumulate photo-charge (hereafter, “charge”) in proportion to an quantity of received electromagnetic energy (e.g., electromagnetic energy in the visible and/or or infrared light spectrums) (hereafter generically, “incident light”). In this regard, the photoelectric conversion device PD may include a photodiode, a photo transistor, a photo gate, and/or a pinned photodiode (PPD).

The transmission transistor TX may operate in response to a transmission control signal received at the transmission gate TG. Thus, the transmission gate TG may transmit charge to the floating diffusion region FD, as generated by the photoelectric conversion device PD. The floating diffusion region FD may receive and accumulate (or store) charge generated by the photoelectric conversion device PD. Thus, charge generated by the photoelectric conversion device PD may be transmitted to the floating diffusion region FD by the transmission transistor TX and accumulated. The drive transistor DX may be controlled in response to an amount of accumulated charge in the floating diffusion region FD.

The reset transistor RX may be used to periodically reset phot-charge accumulated in the floating diffusion region FD. In this regard, the reset transistor RX may be operated in response to a reset control signal received at the reset gate RG. Further, a drain electrode of the reset transistor RX may be connected to the floating diffusion region FD, and a source electrode of the reset transistor RX may be connected to a power supply voltage VDD.

When the reset transistor RX is turned ON by the reset control signal, the power supply voltage VDD connected to the source electrode of the reset transistor RX is transmitted to the floating diffusion region FD. When the reset transistor RX is turned ON, charge accumulated in the floating diffusion region FD may be discharged to reset the floating diffusion region FD. The reset transistor RX may reset a voltage of the floating diffusion region FD to the power supply voltage VDD.

The drive transistor DX is connected to a current source (not shown) located outside the plurality of pixels PX and operates as a source follower buffer amplifier. The drive transistor DX may amplify the charge accumulated in the floating diffusion region FD and transmit the resulting amplified charge to the selection transistor SX. The drive transistor DX amplifies a potential change in the floating diffusion region FD and outputs the amplified potential change as an output voltage Vout.

The selection transistor SX may select a plurality of pixels PX in units of rows. The selection transistor SX may select a pixel by a selection control signal transmitted to the selection gate SG. When the selection transistor SX is turned ON, the power supply voltage VDD may be transmitted to a source electrode of the selection transistor SX. The selection transistor SX may be operated by the selection control signal, and may perform switching and addressing operations. When the selection control signal is applied to the selection transistor SX, the selection transistor SX may output the output voltage Vout connected to the pixel.

FIG. 3 is a plan (or top-down) view of the image sensor 100 of FIGS. 1 and 2. For simplicity and clarity of explanation, FIG. 3 shows only a first pixel PX1, a second pixel PX2, a third pixel PX3 and a fourth pixel PX4 arranged on a pixel isolation structure 150.

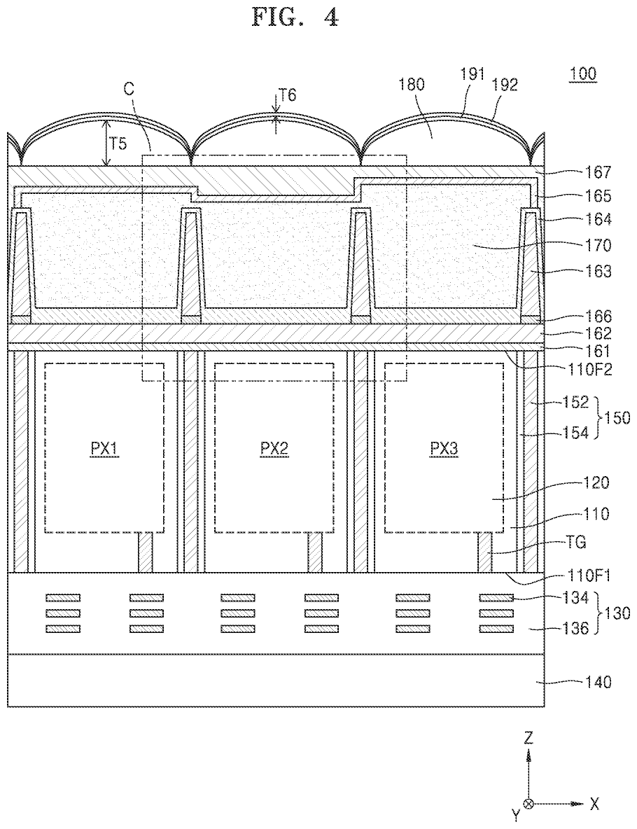

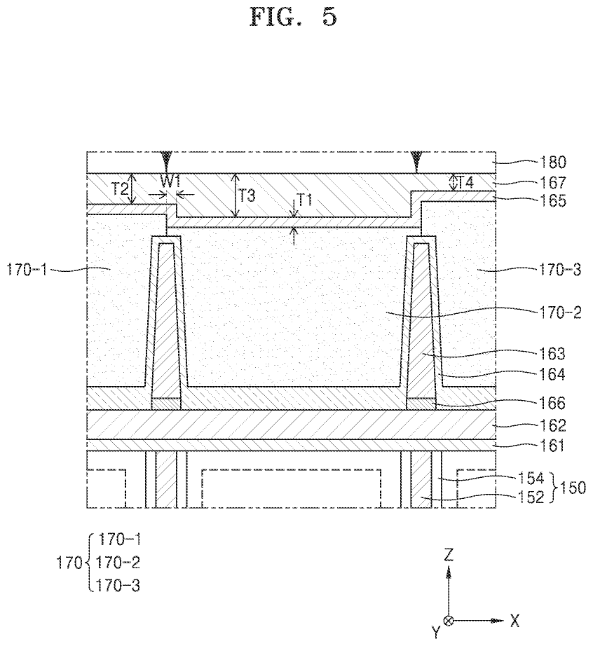

FIG. 4 is a cross-sectional view of the image sensor 100 taken along line A-A′ of FIG. 3, and FIG. 5 is an enlarged view of region ‘C’ indicated in FIG. 4.

Referring to FIGS. 1, 2, 3, 4, and 5, the image sensor 100 may include a substrate 110, a photoelectric conversion region 120, a transmission gate TG, a front side structure 130, a support substrate 140, a pixel isolation structure 150, a first rear side anti-reflective layer 162, a fence 163, a second rear side anti-reflective layer 164, a barrier metal layer 166, a third rear side anti-reflective layer 161, a color filter cover layer 165, a passivation layer 167, a color filter 170, a microlens 180, a first capping layer 191, and a second capping layer 192. The substrate 110 of FIGS. 3, 4 and 5 may correspond to the first substrate 2 of FIG. 1, and the support substrate 140 of FIGS. 3, 4 and 5 may correspond to the second substrate 7 of FIG. 1.

The substrate 110 may include a primary first surface 110F1 and an opposing primary second surface 110F2. In some embodiments, the substrate 110 may include a semiconductor material, such as a group IV semiconductor material, a group III-V semiconductor material, or a group II-VI semiconductor material. The group IV semiconductor material may include, for example, silicon (Si), germanium (Ge), or silicon (Si)-germanium (Ge). The group III-V semiconductor material may include, for example, gallium arsenic (GaAs), indium phosphorus (InP), gallium phosphorus (GaP), indium arsenic (InAs), indium antimony (InSb), or indium gallium arsenic (InGaAs). The group II-VI semiconductor material may include, for example, zinc telluride (ZnTe) or cadmium sulfide (CdS).

The substrate 110 may include a P-type semiconductor substrate (e.g., a P-type silicon substrate). In some embodiments, the substrate 110 may include a P-type bulk substrate and a P-type and/or N-type epitaxial layer grown thereon. In some embodiments, the substrate 110 may include an N-type bulk substrate and a P-type and/or N-type epitaxial layer grown thereon. Alternatively, the substrate 110 may include an organic plastic substrate.

The photoelectric conversion region 120 may be configured within the substrate 110. In the photoelectric conversion region 120, incident light may be converted into a corresponding electrical signal. The photoelectric conversion region 120 may include a photodiode region (not shown) and a well region (not shown) formed inside the substrate 110. The photoelectric conversion region 120 may include impurity regions doped with conductive impurities opposite to that of the principal conductivity type of the substrate 110.

The transmission gate TG may be arranged in the substrate 110. That is, the transmission gate TG may extend from the first surface 110F1 of the substrate 110 into the substrate 110. The transmission gate TG may be a portion of the transmission transistor TX. (See, e.g., FIG. 2). The first surface 110F1 of the substrate 110 may have formed thereon, for example, a transmission transistor TX configured to transmit charge generated in the photoelectric conversion region 120 to a floating diffusion region FD, a reset transistor RX configured to periodically reset the charge stored in the floating diffusion region FD, a drive transistor DX configured to operate as a source follower buffer amplifier and buffer a signal according to the charge accumulated in the floating diffusion region FD, and a selection transistor SX operating as a switching and addressing element selecting among the plurality of pixels PX.

Although not shown in FIG. 4, a device isolation layer for defining an active region and the floating diffusion region FD may also be formed on the first surface 110F1 of the substrate 110.

The photoelectric conversion region 120, the transmission gate TG, a plurality of transistors, and the floating diffusion region FD may form a pixel PX. Hereafter, the various components of the pixel PX will be described in some additional detail with reference to FIG. 4.

As noted above, the plurality of pixels PX may be arranged in a matrix of rows and columns according to a defined two dimensional convention. For example, the second pixel PX2 and the third pixel PX3 may be spaced apart (or separated) from the first pixel PX1 in a first horizontal direction (e.g., the X direction), and the fourth pixel PX4 may be spaced apart from the third pixel PX3 in a second horizontal direction (e.g., the Y direction). The fourth pixel PX4 may be spaced apart from the second pixel PX2 in a diagonal direction (a D direction). In some embodiments, the first horizontal direction may be substantially perpendicular to the second horizontal direction. In some embodiments, the diagonal direction may be inclined with respect to the first horizontal direction and the second horizontal direction. Thus, in some embodiments, the diagonal direction may form a 45° angle between the first horizontal direction and the second horizontal direction. However, in other embodiments, the diagonal direction may form a different angle between the first horizontal direction and the second horizontal direction.

The pixel isolation structure 150 may pass through the substrate 110, and may physically and electrically isolate one pixel PX from another (e.g. adjacent) pixel PX, For example, the third pixel PX3 may be isolated from the second pixel PX2, and the third pixel PX3 may be isolated from the fourth pixel PX4. As may be seen in FIG. 3, the pixel isolation structure 150 may be disposed in a mesh or grid shape in order to variously extend between the plurality of pixels PX. That is, the pixel isolation structure 150 may variously extend between the first pixel PX1 and the second pixel PX2, between the first pixel PX1 and the third pixel PX3, between the second pixel PX2 and the fourth pixel PX4, and between the third pixel PX3 and the fourth pixel PX4. As shown in FIG. 4, the pixel isolation structure 150 may extend from the first surface 110F1 to the second surface 110F2 of the substrate 110.

In some embodiments, the pixel isolation structure 150 may include a conductive layer 152 and an insulating liner 154. Each of the conductive layer 152 and the insulating liner 154 may pass through the substrate 110 from the first surface 110F1 to the second surface 110F2 of the substrate 110. The insulating liner 154 may be arranged between the substrate 110 and the conductive layer 152 to electrically isolate the conductive layer 152 from the substrate 110. In some embodiments, the conductive layer 152 may include a conductive material (e.g., polysilicon and/or a metal or metal alloy). In some embodiments, the insulating liner 154 may include metal oxide (e.g., hafnium oxide, aluminum oxide, and/or tantalum oxide). Assuming the foregoing examples, the insulating liner 154 may operate as a negative fixed charge layer. In some embodiments, the insulating liner 154 may include one or more insulating material(s) (e.g., silicon oxide, silicon nitride and/or silicon oxynitride).

The front side structure 130 may be disposed on the first surface 110F1 of the substrate 110. The front side structure 130 may include a wiring layer 134 and an insulating layer 136. The insulating layer 136 may electrically isolate the wiring layer 134 from the first surface 110F1 of the substrate 110.

The wiring layer 134 may be electrically connected to a transistor on the first surface 110F1 of the substrate 110. The wiring layer 134 may include tungsten, aluminum, copper, tungsten silicide, titanium silicide, tungsten nitride, titanium nitride, doped polysilicon, or the like. The insulating layer 136 may include an insulating material, such as silicon oxide, silicon nitride, silicon oxynitride, or a low-k material. The low-k material may include at least one of, for example, flowable oxide (FOX), torene silazene (TOSZ), undoped silica glass (USG), borosilica glass (BSG), phosphosilica glass (PSG), borophosphosilica glass (BPSG), plasma enhanced tetra ethyl ortho silicate (PETEOS), fluoride silicate glass (FSG), carbon doped silicon oxide (CDO), xerogel, aerogel, amorphous fluorinated carbon, organo silicate glass (OSG), perylene, bis-benzocyclobutene (BCB), silk, polyimide, porous polymeric material, and a combination thereof, but is not limited thereto.

Alternately, the support substrate 140 may be disposed on the front side structure 130. An adhesive element (not shown) may be further arranged between the support substrate 140 and the front side structure 130.

The first rear side anti-reflective layer 162 may be disposed on the second surface 110F2 of the substrate 110. In other words, the first rear side anti-reflective layer 162 may be disposed on all pixels PX and the pixel isolation structure 150. In some embodiments, the first rear side anti-reflective layer 162 may include hafnium oxide. In some embodiments, the first rear side anti-reflective layer 162 may include at least one of silicon nitride (SiN), aluminum oxide (Al₂O₃), zirconium oxide (ZrO₂), tantalum oxide (Ta₂O₅), titanium oxide (TiO₂), lanthanum oxide (La₂O₃), praseodymium oxide (Pr₂O₃), cerium oxide (CeO₂), neodymium oxide (Nd₂O₃), promethium oxide (Pm₂O₃), samarium oxide (Sm₂O₃), europium oxide (Eu₂O₃), gadolinium oxide (Gd₂O₃), terbium oxide (Tb₂O₃), dysprosium oxide (Dy₂O₃), holmium oxide (Ho₂O₃), thulium oxide (Tm₂O₃), ytterbium oxide (Yb₂O₃), lutetium oxide (Lu₂O₃), and/or yttrium oxide (Y₂O₃).

The fence 163 may be disposed on the first rear side anti-reflective layer 162. In the plan view, the fence 163 may overlap the pixel isolation structure 150 in a vertical direction (a Z direction). That is, the fence 163 may extend between the pixels PX. For example, the fence 163 may extend between the first pixel PX1 and the second pixel PX2, between the first pixel PX1 and the third pixel PX3, between the second pixel PX2 and the fourth pixel PX4, and between the third pixel PX3 and the fourth pixel PX4.

In some embodiments, the fence 163 may include a low refractive index material. In this regard, the term “low refractive index material” may be understood as a material having a refractive index greater than about 1.0 and less than or equal to about 1.4. For example, the low refractive index material may include polymethylmethacrylate (PMMA), silicon acrylate, cellulose acetate butyrate (CAB), silica, and/or fluoro-silicon acrylate (FSA). Alternately or additionally, the low refractive index material may include a polymer material in which silica (SiOₓ) particles are dispersed.

When the fence 163 includes a low refractive index material, incident light directed towards the fence 163 may be fully reflected towards the center of the pixel PX. That is, the fence 163 may prevent incident light from leaking obliquely from one color filter 170 disposed on one pixel PX to another color filter 170 disposed on an adjacent pixel PX, thereby preventing crosstalk between the adjacent pixels.

The second rear side anti-reflective layer 164 may be disposed on the first rear side anti-reflective layer 162 and the fence 163. That is, the second rear side anti-reflective layer 164 may cover the first rear side anti-reflective layer 162 and the fence 163. For example, the second rear side anti-reflective layer 164 may be arranged on an upper surface of the first rear side anti-reflective layer 162, a side surface of the fence 163, and an upper surface of the fence 163.

In some embodiments, the second rear side anti-reflective layer 164 may include silicon oxide. More generally, in some embodiments, the second rear side anti-reflective layer 164 may include at least one of silicon nitride (SiN), hafnium oxide (HfO₂), aluminum oxide (Al₂O₃), zirconium oxide (ZrO₂), tantalum oxide (Ta₂O₅), titanium oxide (TiO₂), lanthanum oxide (La₂O₃), praseodymium oxide (Pr₂O₃), cerium oxide (CeO₂), neodymium oxide (Nd₂O₃), promethium oxide (Pm₂O₃), samarium oxide (Sm₂O₃), europium oxide (Eu₂O₃), gadolinium oxide (Gd₂O₃), terbium oxide (Tb₂O₃), dysprosium oxide (Dy₂O₃), holmium oxide (Ho₂O₃), thulium oxide (Tm₂O₃), ytterbium oxide (Yb₂O₃), lutetium oxide (Lu₂O₃), and/or yttrium oxide (Y₂O₃).

The barrier metal layer 166 may be disposed on a lower surface of the fence 163. That is, the barrier metal layer 166 may be arranged between the fence 163 and the first rear side anti-reflective layer 162. In some embodiments, the barrier metal layer 166 may include barrier metal, such as titanium nitride.

The third rear side anti-reflective layer 161 may be arranged between the first rear side anti-reflective layer 162 and the pixels PX, and between the first rear side anti-reflective layer 162 and the pixel isolation structure 150. That is, the third rear side anti-reflective layer 161 may be arranged between the first rear side anti-reflective layer 162 and the substrate 110. In some embodiments, the third rear side anti-reflective layer 161 may include, for example, aluminum oxide. More generally, in some embodiments, the third rear side anti-reflective layer 161 may include at least one of silicon nitride (SiN), hafnium oxide (HfO₂), zirconium oxide (ZrO₂), tantalum oxide (Ta₂O₅), titanium oxide (TiO₂), lanthanum oxide (La₂O₃), praseodymium oxide (Pr₂O₃), cerium oxide (CeO₂), neodymium oxide (Nd₂O₃), promethium oxide (Pm₂O₃), samarium oxide (Sm₂O₃), europium oxide (Eu₂O₃), gadolinium oxide (Gd₂O₃), terbium oxide (Tb₂O₃), dysprosium oxide (Dy₂O₃), holmium oxide (Ho₂O₃), thulium oxide (Tm₂O₃), ytterbium oxide (Yb₂O₃), lutetium oxide (Lu₂O₃) and/or yttrium oxide (Y₂O₃).

The color filter cover layer 165 may be arranged to cover a portion of an upper surface and a side surface of each of a plurality of color filters 170. For example, the color filter cover layer 165 may be arranged to conformally cover a portion of an upper surface and a side surface of each of a plurality of color filters 170. The color filter cover layer 165 may be disposed to protect a plurality of color filters 170. In some embodiments, the color filter cover layer 165 may include silicon oxide and/or aluminum oxide. More generally, in some embodiments, the color filter cover layer 165 may include at least one of silicon nitride (SiN), hafnium oxide (HfO₂), aluminum oxide (Al₂O₃), zirconium oxide (ZrO₂), tantalum oxide (Ta₂O₅), titanium oxide (TiO₂), lanthanum oxide (La₂O₃), praseodymium oxide (Pr₂O₃), cerium oxide (CeO₂), neodymium oxide (Nd₂O₃), promethium oxide (Pm₂O₃), samarium oxide (Sm₂O₃), europium oxide (Eu₂O₃), gadolinium oxide (Gd₂O₃), terbium oxide (Tb₂O₃), dysprosium oxide (Dy₂O₃), holmium oxide (Ho₂O₃), thulium oxide (Tm₂O₃), ytterbium oxide (Yb₂O₃), lutetium oxide (Lu₂O₃) and/or yttrium oxide (Y₂O₃). A first thickness T1 associated the color filter cover layer 165 (“thickness” being measured, for example, in the vertical (or Z) direction) may range from between about 5 nm to about 35 nm. In this regard, the color filter cover layer 165 may have the same first thickness T1 notwithstanding the thickness of other color filters 170. In addition, a first width W1 associated with the color filter cover layer 165 (“width” being measured, for example, in the first horizontal direction) may range from between about 5 nm to about 35 nm.

The passivation layer 167 may be disposed on the second rear side anti-reflective layer 164 and the color filter cover layer 165. Thus, the passivation layer 167 may be used to protect the first rear side anti-reflective layer 162, the fence 163, the second rear side anti-reflective layer 164, and the color filter cover layer 165. In some embodiments, the passivation layer 167 may include, for example, a resin-based material, such as a styrene-based resin, an acrylic resin, a styrene-acrylic copolymer resin, and/or a siloxane-based resin. The thickness of the passivation layer 167 may vary according to the thickness of each of the plurality of color filters 170. For example, the thickness of the passivation layer 167 may include a second thickness T2, a third thickness T3, and a fourth thickness T4, wherein in some embodiments, the second thickness T2 may range from between about 50 nm to about 200 nm, the third thickness T3 may range from between about 100 nm to about 250 nm, and the fourth thickness T4 may be less than or equal to about 50 nm.

In some embodiments, a lower surface of the passivation layer 167 may include a stepped portion, whereas an upper surface of the passivation layer 167 may be substantially flat.

The plurality of color filters 170 may be disposed on the passivation layer 167, and may be isolated from each other by the fence 163. The plurality of color filters 170 may be arranged to respectively correspond to the pixels PX. The plurality of color filters 170 may include, for example, a combination of color filters including at least one of a green filter, a blue filter, and a red filter. Alternately or additionally, the plurality of color filters 170 may include, for example, a combination of color filters including at least one of a cyan filter, a magenta filter, and a yellow color filter. More generally, the plurality of color filters 170 may include at least one of a first color filter 170-1, a second color filter 170-2, and a third color filter 170-3, wherein the first color filter 170-1, the second color filter 170-2, and the third color filter 170-3 are associated with different colors.

In some embodiments, the respective lower surfaces of the plurality of color filters 170 may be disposed at the same vertical level, whereas the respective upper surfaces of the plurality of color filters 170 may be disposed at different vertical levels. In this regard, the term “level” is used to denote relative disposition, as measured for example in the vertical direction, of the various surfaces in relation to an arbitrarily selected horizontal surface (e.g., a surface associated with an anti-reflective layer, a surface associated with the support substrate 140, a surface associated with the substrate 110, etc.).

In some embodiments, the red filter may have a greatest thickness, the green filter may have a thickness greater than that of the blue filter yet less than that of the red filter, and the blue filter may have a thickness less than either of the red filter and green filter. More generally, in some embodiments, a first thickness of the first color filter 170-1 may be less than a second thickness of the second color filter 170-2 and a third thickness of the third color filter 170-3, and the second thickness of the second color filter 170-2 may be less than the third thickness of the third color filter 170-3. However, various relationship(s) between the respective thicknesses of the red filter, the green filter, and the blue filter may vary according to design.

Accordingly, a fourth thickness T4 of the passivation layer 167 disposed on the third color filter 170-3 may be less than a second thickness T2 of the passivation layer 167 disposed on the first color filter 170-1, and the second thickness T2 of the passivation layer 167 disposed on the first color filter 170-1 may be less than a third thickness T3 of the passivation layer 167 disposed on the second color filter 170-2.

The microlens 180 may be disposed on the color filters 170 and the passivation layer 167. That is, in some embodiments, the microlens 180 may be arranged to correspond with the respective pixels PX. In some embodiments, the microlens 180 may be substantially transparent. That is, for example, the microlens 180 may exhibit an optical transmittance that is greater than or equal to about 90% with respect to incident light for a same area, as defined for a particular bandwidth of electromagnetic energy (e.g., visible light having a wavelength that ranges from 380 nm to about 770 nm).

In some embodiments, the microlens 180 may be formed using a reflowing photoresist. For example, the microlens 180 may include at least one “high refractive index material” exhibiting a refractive index greater than or equal at least about 1.7. In some embodiments, the microlens 180 may be formed, for example, from a resin-based material, such as a styrene-based resin, an acrylic resin, a styrene-acrylic copolymer resin, or a siloxane-based resin. The microlens 180 may be used to concentrate (or focus) incident light, such that resulting concentrated light is directed to the photoelectric conversion region 120 through the color filters 170. In some embodiments, the microlens 180 may have a fifth thickness T5 ranging from between about 200 nm to about 500 nm.

The first capping layer 191 may be disposed on the microlens 180, and the second capping layer 192 may be disposed on the first capping layer 191. The second capping layer 192 may be formed to conformally cover the first capping layer 191. The second capping layer 192 may be conformally coated on the first capping layer 191 to readily protect a trough structure formed by a plurality of microlenses 180 having a curved structure. Accordingly, the second capping layer 192 may readily protect the image sensor 100 from external contamination. The second capping layer 192 may have a sixth thickness T6 ranging from between about 5 nm to about 35 nm.

In some embodiments, the first capping layer 191 may include a porous material. The second capping layer 192 may include silicon oxide and/or aluminum oxide.

More generally, in some embodiments, the second capping layer 192 may include at least one of silicon nitride (SiN), hafnium oxide (HfO₂), zirconium oxide (ZrO₂), tantalum oxide (Ta₂O₅), titanium oxide (TiO₂), lanthanum oxide (La₂O₃), praseodymium oxide (Pr₂O₃), cerium oxide (CeO₂), neodymium oxide (Nd₂O₃), promethium oxide (Pm₂O₃), samarium oxide (Sm₂O₃), europium oxide (Eu₂O₃), gadolinium oxide (Gd₂O₃), terbium oxide (Tb₂O₃), dysprosium oxide (Dy₂O₃), holmium oxide (Ho₂O₃), thulium oxide (Tm₂O₃), ytterbium oxide (Yb₂O₃), lutetium oxide (Lu₂O₃) and/or yttrium oxide (Y₂O₃).

In some embodiments, the density of material(s) (hereafter, “material density”) used to form the second capping layer 192 may be greater than a material density of the first capping layer 191. That is, the second capping layer 192 may include one or more material(s) having a density that is greater than the density of material(s) included in the first capping layer 191.

Those skilled in the art will recognize that the structure of conventional image sensors inadequately protect their constituent color filters making them relatively more susceptible to contamination, as compared with embodiments of the inventive concept. That is, the image sensors according to embodiments of the inventive concept include the color filter cover layer 165 coated on the color filter 170 that's protects the color filters 170 from contamination, thereby improving overall reliability of the image sensor.

Those skilled in the art will further appreciate that conventional image sensors do not include a color filter cover layer like that described above in relation to certain embodiments of the inventive concept. Accordingly, such conventional image sensors include a relatively thicker passivation layer which results in a relatively thicker image sensor, thereby inhibiting efforts to reduce the overall size of a semiconductor package including such image sensors. In contrast, the color filter cover layer 165 described above in relation to image sensor 100 is characterized by a thinner passivation layer 167, enabling relative reduction in the size of a semiconductor package including image sensor(s) according to embodiments of the inventive concept.

Those skilled in the art will still further appreciate that image sensors according to embodiments of the inventive concept may include two capping layers that effectively protect the microlens 180 from external contamination. In particular, the second capping layer 192 may be conformally coated on the microlens 180 and the first capping layer 191 to protect even trough portion(s) of the microlens 180, thereby reducing crosstalk and improving overall image quality.

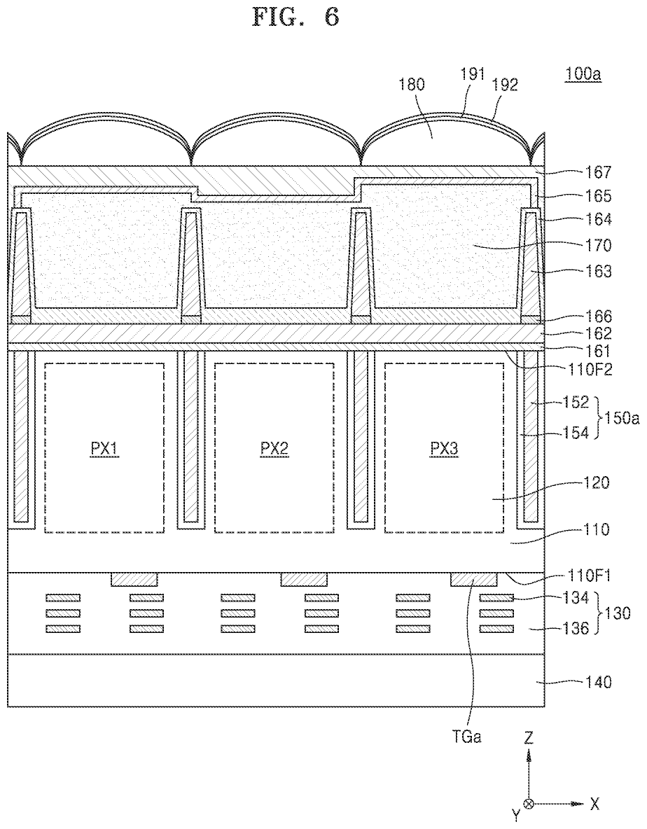

FIG. 6 is a cross-sectional view illustrating another image sensor 110a according to embodiments of the inventive concept. Hereinafter, only material differences between the image sensor 100 of FIGS. 3, 4 and 5 and the image sensor 100a of FIG. 6 will be described.

Referring to FIG. 6, the image sensor 100a may include a pixel isolation structure 150a instead of the pixel isolation structure 150 of FIG. 4, wherein the pixel isolation structure 150a does not fully extend through the substrate 110. That is, the pixel isolation structure 150a may extend from the second surface 110F2 of the substrate 110 into the substrate 110, but not reach the first surface 110F1 of the substrate 110.

In addition, the image sensor 100a may include a transmission gate TGa instead of the transmission gate TG of FIG. 4, wherein the transmission gate TGa may be formed on the first surface 110F1 of the substrate 110, but not extend into the substrate 110.

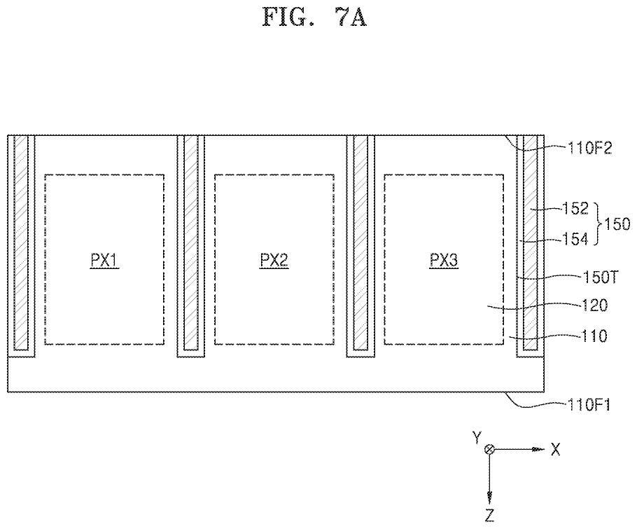

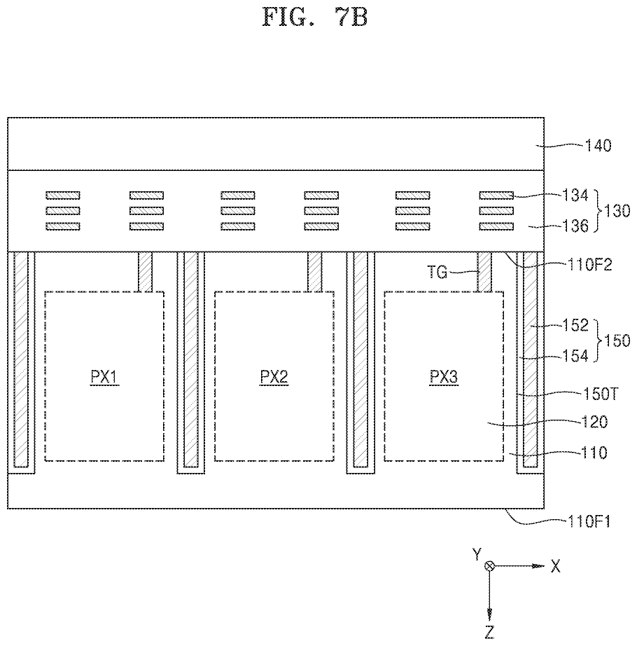

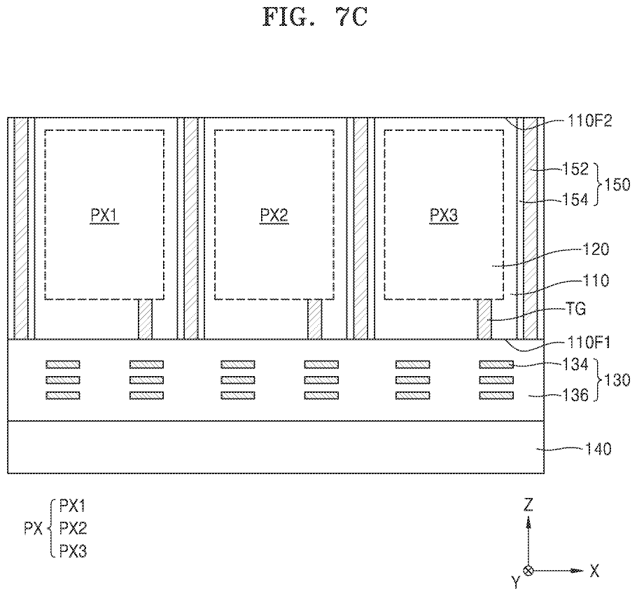

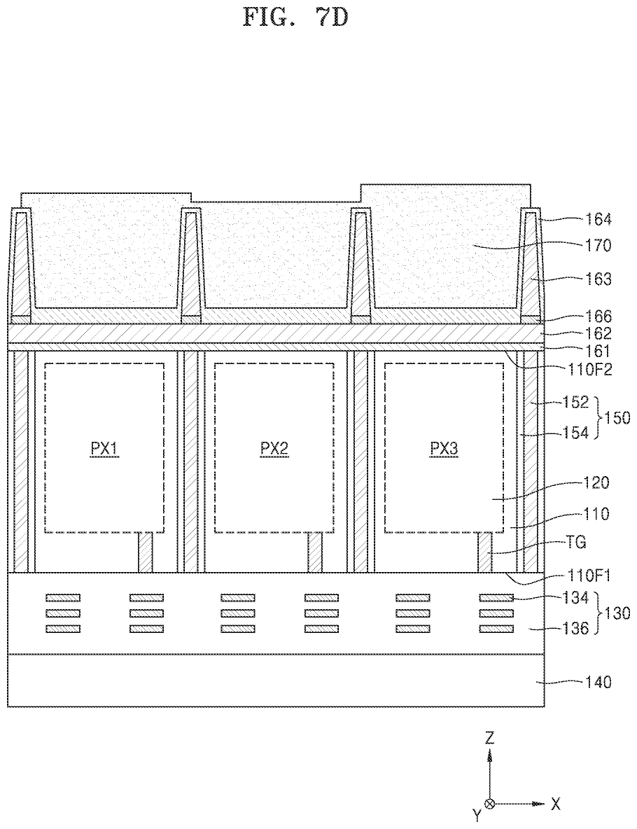

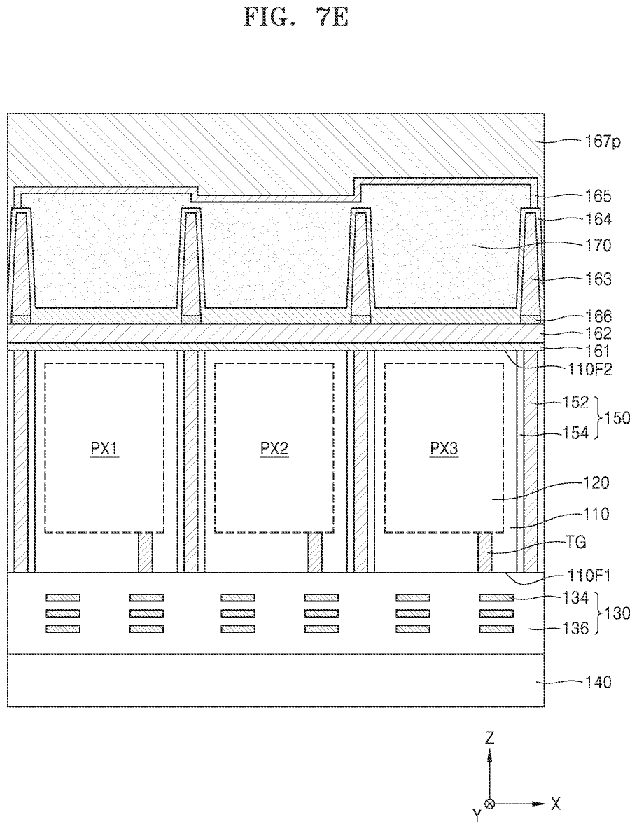

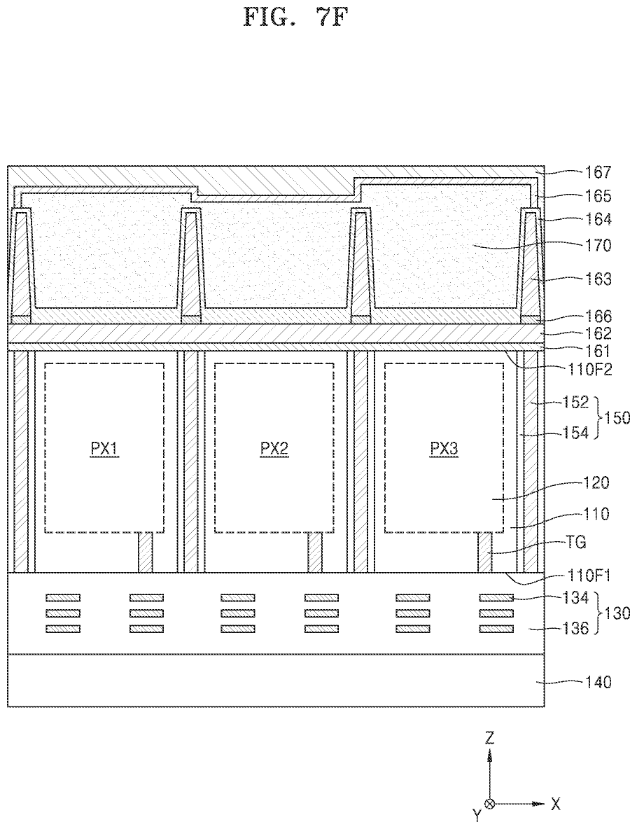

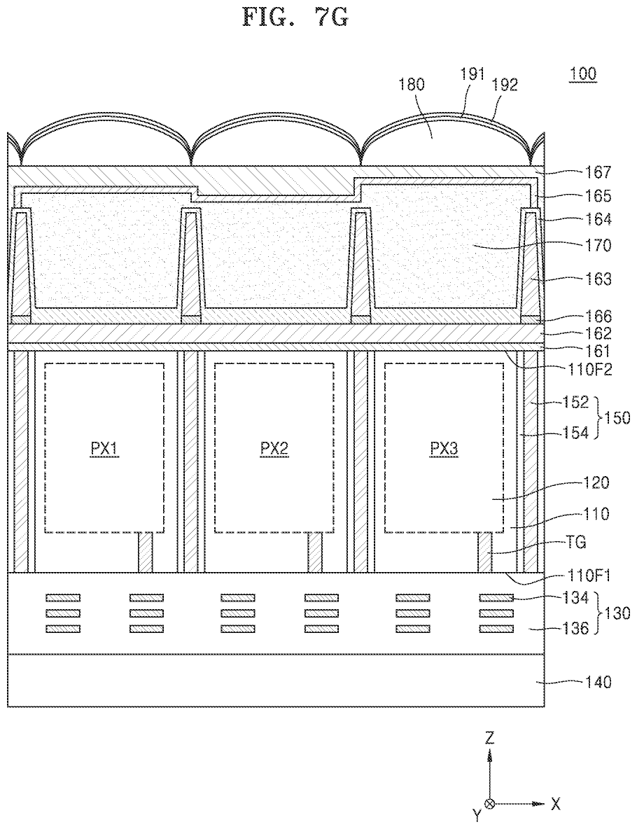

FIGS. 7A to 7G are related cross-sectional views illustrating in one example a method of manufacturing the image sensor 100 of FIGS. 3 and 4 according to embodiments of the inventive concept.

Referring to FIG. 7A, the substrate 110 including the first surface 110F1 and the opposing second surface 110F2 is provided. A mask pattern (not shown) may be formed on the first surface 110F1 of the substrate 110, and a trench 150T may be formed by removing a portion of the substrate 110 from the first surface 110F1 of the substrate 110 using the mask pattern.

Subsequently, the insulating liner 154 and the conductive layer 152 may be sequentially formed within the trench 150T, and the pixel isolation structure 150 may be formed within the trench 150T by selectively removing (e.g., by use of a planarization process) portions of the insulating liner 154 and the conductive layer 152 disposed on the first surface 110F1 of the substrate 110.

Subsequently, the photoelectric conversion region 120 including a photodiode region (not shown) and a well region (not shown) may be formed from the first surface 110F1 of the substrate 110 using, e.g., an ion implantation process. For example, the photodiode region may be formed by selective doping of N-type impurities, and the well region may be formed by selective doping of P-type impurities.

Referring to FIG. 7B, the transmission gate TG extending from the first surface 110F1 of the substrate 110 into the substrate 110 may be formed, and a floating diffusion region (not shown) and an active region (not shown) may be formed by performing an ion implantation process on a partial region on the first surface 110F1 of the substrate 110. Accordingly, the first pixel PX1, the second pixel PX2, and the third pixel PX3 may be formed.

Next, the front side structure 130 may be formed on the first surface 110F1 of the substrate 110. The wiring layer 134 and the insulating layer 136 may be formed on the substrate 110 by repeatedly performing operations of forming a conductive layer (not shown) on the first surface 110F1 of the substrate 110, patterning the conductive layer, and forming an insulating layer (not shown) to cover the patterned conductive layer. Subsequently, the support substrate 140 may be mounted on (or adhered to) the insulating layer 136.

Referring to FIG. 7C, the substrate 110 may be flipped (i.e., turned upside down), such that the second surface 110F2 of the substrate 110 is upwardly exposed. Next, a portion of the substrate 110 may be removed from the second surface 110F2 of the substrate 110 using a planarization process (e.g., a chemical mechanical polishing (CMP) process or an etch back process), such that the conductive layer 152 is exposed. As the removal process is performed, the vertical profile of the second surface 110F2 of the substrate 110 may be reduced. In this case, one pixel PX surrounded by the pixel isolation structure 150 may be physically and electrically isolated from a pixel PX adjacent thereto.

Referring to FIG. 7D, the third rear side anti-reflective layer 161, the first rear side anti-reflective layer 162, the barrier metal layer 166, the fence 163, the second rear side anti-reflective layer 164, and the plurality of color filters 170 may be sequentially formed on the second surface 110F2 of the substrate 110. In some embodiments, the third rear side anti-reflective layer 161 may be formed of aluminum oxide, the first rear side anti-reflective layer 162 may be formed of hafnium oxide, the second rear side anti-reflective layer 164 may be formed of silicon oxide, the barrier metal layer 166 may be formed of titanium nitride, and the fence 163 may be formed of a low refractive index material. The second rear side anti-reflective layer 164 may be formed by a deposition method having high straightness, such as evaporation.

Referring to FIG. 7E, the color filter cover layer 165 and the spare passivation layer 167p may be formed on the plurality of color filters 170. The color filter cover layer 165 may be conformally formed on the plurality of color filters 170. For example, the color filter cover layer 165 may include oxide, such as silicon oxide and/or aluminum oxide. The color filter cover layer 165 may be formed on the color filter 170 using an atomic layer deposition (ALD) method. In some embodiments, the color filter cover layer 165 may be formed on the color filter 170 using a chemical vapor deposition (CVD) and/or molecular vapor deposition (MVD) method.

The spare passivation layer 167p may be formed on the color filter cover layer 165 and the second rear side anti-reflective layer 164. The spare passivation layer 167p may be formed of a resin-based material, such as a styrene-based resin, an acrylic resin, a styrene-acrylic copolymer resin, or a siloxane-based resin.

Referring to FIG. 7F, the passivation layer 167 may be formed by etching an upper surface of the spare passivation layer 167p. (Compare FIG. 7E). A portion of the upper surface of the spare passivation layer 167p (refer to FIG. 7E) may be removed by a planarization process such as a CMP process or an etch back process.

The color filter cover layer 165 formed of oxide may operate as an etch stop layer when etching the spare passivation layer 167p. (See, FIG. 7E). Therefore, an additional etch stop layer does not need to be formed, and thus, the overall manufacturing process may be simplified and manufacturing cost/time may be reduced accordingly.

Referring to FIG. 7G, a microlens material layer (not shown) may be formed on the color filter 170 and the passivation layer 167, and a mask pattern (not shown) may be formed on the microlens material layer.

Next, the mask pattern may be transformed into a hemispherical shape by performing a reflow process. In some embodiments, the reflow process may be performed at a temperature ranging from between about 100° C. to about 200° C. for a period of time ranging from between about several seconds to about several tens of minutes, but the scope of the inventive concept is not limited thereto. Next, a microlens 180 may be formed by etching the microlens material layer by using the mask pattern as an etching mask.

Subsequently, the first capping layer 191 and the second capping layer 192 may be formed on the microlens 180 in order to materially complete the manufacture of the image sensor 100 shown in FIG. 4.

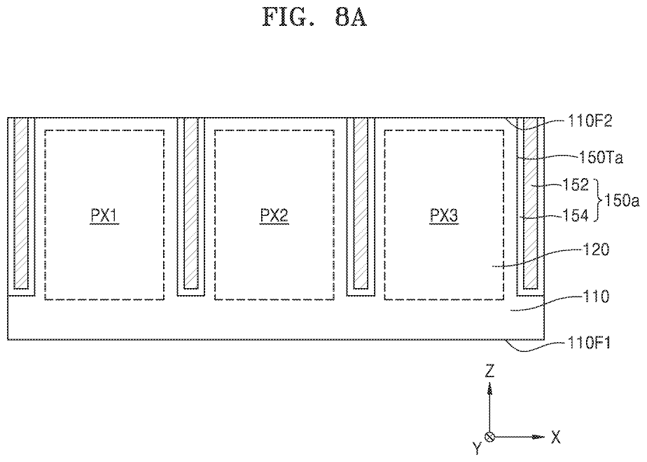

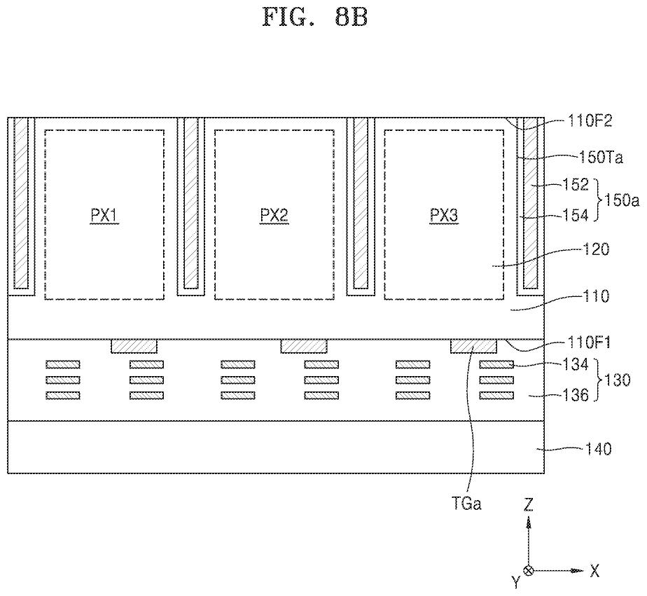

FIGS. 8A and 8B are related cross-sectional views illustrating in one example a method of manufacturing the image sensor 100a of FIG. 6 according to embodiments of the inventive concept.

Referring to FIG. 8A, the photoelectric conversion region 120 including a photodiode region (not shown) and a well region (not shown) may be formed from the first surface 110F1 of the substrate 110 using an ion implantation process. For example, the photodiode region may be formed by doping N-type impurities, and the well region may be formed by doping P-type impurities.

A mask pattern (not shown) may be formed on the second surface 110F2 of the substrate 110, and a trench 150Ta may be formed by removing a portion of the substrate 110 from the second surface 110F2 of the substrate 110 using the mask pattern.

Thereafter, the insulating liner 154 and the conductive layer 152 may be sequentially formed within the trench 150Ta, and a pixel isolation structure 150a may be formed within the trench 150Ta by removing (e.g., using a planarization process) portions of the insulating liner 154 and the conductive layer 152 disposed on the second surface 110F2 of the substrate 110.

Referring to FIG. 8B, the substrate 110 may be flipped such that the second surface 110F2 of the substrate 110 is upwardly exposed. The transmission gate TGa may then be formed on the first surface 110F1 of the substrate 110, and a floating diffusion region (not shown) and an active region (not shown) may be formed (e.g., using an ion implantation process) on a partial region on the first surface 110F1 of the substrate 110.

Thus, after formation of the first pixel PX1, the second PX2, and the third pixel PX3, the front side structure 130 may be formed on the first surface 110F1 of the substrate 110.

The wiring layer 134 and the insulating layer 136 may be formed on the substrate 110 by repeatedly performing the operations of forming a conductive layer (not shown) on the first surface 110F1 of the substrate 110, patterning the conductive layer, and then forming an insulating layer (not shown) to cover the patterned conductive layer.

Thereafter, the support substrate 140 may be mounted on (e.g., adhered to) the insulating layer 136.

Then, the third rear side anti-reflective layer 161, the first rear side anti-reflective layer 162, the barrier metal layer 166, the fence 163, the second rear side anti-reflective layer 164, the passivation layer 167, the color filter 170, the color filter cover layer 165, the microlens 180, the first capping layer 191 and the second capping layer 192 may be formed in accordance with the method steps described in relation to FIGS. 7D, 7E, 7F and 7G in order to substantially complete the image sensor 100a of FIG. 6.

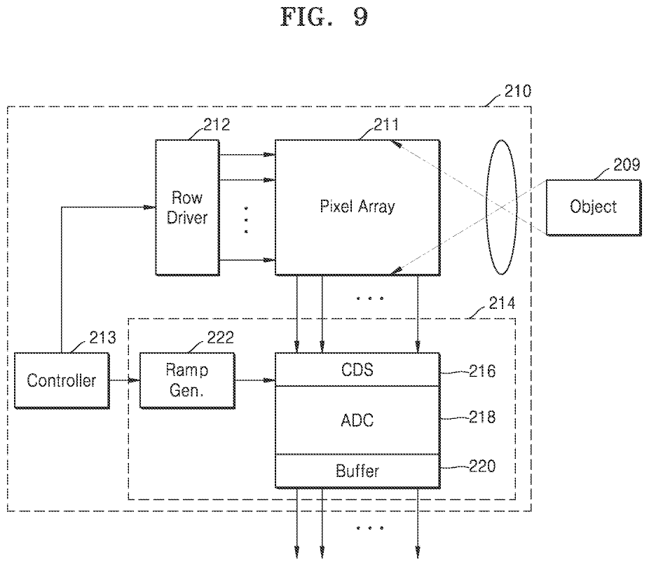

FIG. 9 is a block diagram illustrating an image sensor 210 according to embodiments of the inventive concept.

Referring to FIG. 9, the image sensor 210 may include a pixel array 211, a controller 213, a row driver 212, and a pixel signal processor 214. Here, the image sensor 210 may be implemented, for example, in accordance with the image sensors 100 and 100a described above.

The pixel array 211 may include a plurality of pixels (hereafter, “pixels”) arranged in a two dimensional matrix, wherein each of the pixels includes a photoelectric conversion device. The photoelectric conversion device may generate photo-charge (hereafter, “charge”) by absorbing incident light in order to provide a corresponding electrical signal (e.g., an output voltage (Vout)) which may be provided to the pixel signal processor 214 through a vertical signal line. In this regard, the pixels included in the pixel array 211 may provide the output voltage one at a time in units of rows.

Accordingly, pixels of one row of the pixel array 211 may be simultaneously activated by a selection signal output by the row driver 212. Pixels of a selected row may provide an output line of a corresponding column with an output voltage according to absorbed light.

The controller 213 may control the row driver 212 to allow the pixel array 211 to absorb incident light and accumulate charge or temporarily store the accumulated charge, and to output an electrical signal corresponding to the stored charge to circuit(s) external to the pixel array 211. In addition, the controller 213 may control the pixel signal processor 214 to measure the output voltage provided by the pixel array 211.

The pixel signal processor 214 may include a correlation double sampler (CDS) 216, an analog-to-digital converter (ADC) 218, and a buffer 220. The CDS 216 may sample and hold the output voltage provided by the pixel array 211. The CDS 216 may double-sample a particular noise level and a level corresponding to the generated output voltage, and may output a level corresponding to a difference therebetween. In addition, the CDS 216 may receive ramp signals generated by a ramp signal generator 222, compare the received ramp signals with each other, and output a comparison result. The ADC 218 may convert the analog signal corresponding to the level of charge received from the CDS 216 into a digital signal. The buffer 220 may latch the digital signal, and the latched signal may be sequentially output to circuit(s) external to the image sensor 210 (e.g., an image processor (not shown)).

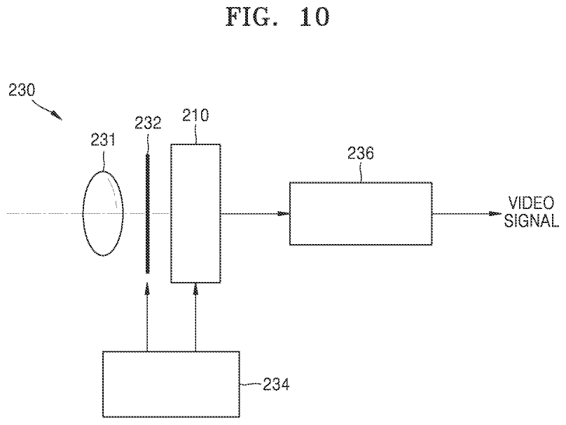

FIG. 10 is a block diagram illustrating a camera 230 that may include at least one image sensor according to embodiments of the inventive concept.

Referring to FIG. 10, the camera 230 may include an image sensor 210, an optical system 231 for guiding incident light to a light receiving sensor unit of the image sensor 210, a shutter device 232, a driving circuit 234 for driving the image sensor 210, and a signal processing circuit 236 for processing an output signal of the image sensor 210.

The image sensor 210 may include at least one image sensor consistent with an embodiment of the inventive concept (e.g., image sensors 100 and 100a described above). The optical system 231 including an optical lens may be capture and focus incident light from a subject on an imaging surface of the image sensor 210. In response, charge will accumulate in the image sensor 210 over a certain period of time.

The optical system 231 may be an optical lens system including a plurality of optical lenses. The shutter device 232 may be used to control a light irradiation (or receiving) period and a light blocking (or non-receiving) period with respect to the image sensor 210. The driving circuit 234 may be used to supply a driving signal to the image sensor 210 and the shutter device 232, and to control a signal output operation of the image sensor 210 to the signal processing circuit 236 and a shutter operation of the shutter device 232 by the supplied driving signal or a timing signal.

The driving circuit 234 may be used to control a signal transmission operation from the image sensor 210 to the signal processing circuit 236 by supplying the driving signal and/or the timing signal. The signal processing circuit 236 performs various types of signal processing on a signal transmitted from the image sensor 210. An image (video) signal on which signal processing is performed is stored in a storage medium, such as a memory, or is output to a monitor.

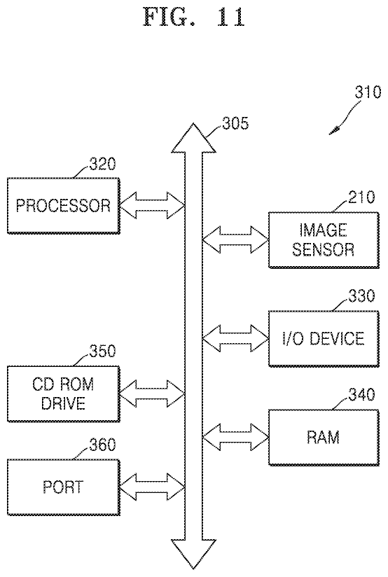

FIG. 11 is a block diagram illustrating an imaging system 310 that may include at least one image sensor according to embodiments of the inventive concept.

Referring to FIG. 11, the imaging system 310 may be a system capable of processing an output image provided by an image sensor 210. Here, the image sensor 210 may be implemented in accordance with an embodiment of the inventive concept, such as for example the image sensors 100 and 100a described above. The imaging system 310 may be any type of electrical and electronic system incorporating the image sensor 210, such as a computer system, a camera system, a scanner, an image safety system, etc.

Assuming that the imaging system 310 is based on a processor (e.g., a computer system), it may include a processor 320 (e.g., a microprocessor or a central processing unit (CPU)) capable of communicating with an input/output (I/O) device 330 through a bus 305. A compact disk Read Only Memory (CD ROM) drive 350, a port 360, and/or random access memory (RAM) 340 may be connected to the processor 320 through the bus 305 to exchange data therebetween, and may reproduce an output image from data provided by the image sensor 210.

Here, the port 360 may be a port capable of coupling a video card, a sound card, a memory card, a Universal Serial Bus (USB) device, or the like, or communicating data with another system. The image sensor 210 may be integrated with processors, such as CPUs, digital signal processors (DSPs), or microprocessors, and may also be integrated with a memory. In some cases, the image sensor 210 may be integrated into a chip separate from a processor. The imaging system 310 may be a system block diagram, such as a camera phone or a digital camera, from among digital devices.

While the inventive concept has been particularly shown and described with reference to certain embodiments thereof, those skilled in the art will understood that various changes in form and detail may be made therein without departing from the scope of the inventive concept, as defined by the following claims.

What is claimed is:

1. An image sensor comprising:
a pixel;
a rear side anti-reflective layer on the pixel;
a color filter on the rear side anti-reflective layer;
a color filter cover layer on the color filter;
a passivation layer on the color filter cover layer;
a microlens on the passivation layer;
a first capping layer on the microlens; and
a second capping layer on the first capping layer.

2. The image sensor of claim 1, wherein a material density of the second capping layer is greater than a material density of the first capping layer.

3. The image sensor of claim 1, wherein the second capping layer includes an oxide.

4. The image sensor of claim 1, wherein the color filter cover layer includes an oxide.

5. The image sensor of claim 1, wherein the color filter cover layer has a thickness ranging from between about 5 nm to about 35 nm.

6. The image sensor of claim 1, the passivation layer has a thickness ranging from about 50 nm to about 250 nm.

7. The image sensor of claim 1, wherein the microlens includes a high refractive index material having a refractive index greater than or equal to about 1.7.

8. An image sensor comprising:
a first pixel;
a second pixel spaced apart from the first pixel;
a pixel isolation structure between the first pixel and the second pixel;
a rear side anti-reflective layer on the first pixel, the second pixel, and the pixel isolation structure;
a color filter on the rear side anti-reflective layer and including a first color filter on the first pixel and a second color filter on the second pixel;
a color filter cover layer on the color filter;
a passivation layer on the color filter cover layer;
a microlens on the passivation layer;
a first capping layer on the microlens; and
a second capping layer on the first capping layer, wherein the color filter cover layer is conformally coated on the color filter.

9. The image sensor of claim 8, wherein an upper surface of the first color filter and an upper surface of the second color filter are disposed at different levels.

10. The image sensor of claim 8, wherein the color filter cover layer covers an upper surface of the first color filter, an upper surface of the second color filter, and at least one of a portion of a side surface of the first color filter and a portion of a side surface of the second color filter.

11. The image sensor of claim 8, wherein a width of a portion of the color filter cover layer covering at least one of a side surface of the first color filter and a side surface of the second color filter ranges from between about 5 nm to about 35 nm.

12. The image sensor of claim 8, wherein the second capping layer is conformally coated on the microlens.

13. The image sensor of claim 8, wherein the color filter cover layer and the second capping layer include a same material.

14. The image sensor of claim 8, wherein the second capping layer has a thickness ranging from between about 5 nm to about 35 nm.

15. The image sensor of claim 8, wherein the microlens has a thickness ranging from between about 200 nm to about 500 nm.

16. An image sensor comprising:
a first pixel;
a second pixel spaced apart from the first pixel;
a pixel isolation structure between the first pixel and the second pixel;
a first rear side anti-reflective layer on the first pixel, the second pixel, and the pixel isolation structure;
a fence on the first rear side anti-reflective layer and aligned with the pixel isolation structure;
a second rear side anti-reflective layer on the first rear side anti-reflective layer and the fence;
a color filter on the second rear side anti-reflective layer and including a first color filter on the first pixel and a second color filter on the second pixel;
a color filter cover layer on the color filter;
a passivation layer on the color filter cover layer;
a microlens on the passivation layer;
a first capping layer on the microlens; and
a second capping layer on the first capping layer, wherein the color filter cover layer is conformally coated on the color filter, and the second capping layer is conformally coated on the microlens.

17. The image sensor of claim 16, wherein an upper surface of the passivation layer is flat, and a lower surface of the passivation layer includes a stepped portion.

18. The image sensor of claim 16, wherein the passivation layer and the microlens include different materials.

19. The image sensor of claim 16, wherein the first color filter has a thickness greater than that of the second color filter,
the first color filter includes at least one of a red filter and a green filter, and
the second color filter includes at least one of a green filter and a blue filter.

20. The image sensor of claim 16, wherein the first color filter has a thickness greater than that of the second color filter, and
the color filter cover layer covers an upper surface of the first color filter, an upper surface of the second color filter, and a side surface of the first color filter.
